(19) United States
(12) Patent Application Publication
(10) Pub. No.: US 2020/0396860 A1
(43) Pub. Date: Dec. 17, 2020

(54) ELECTRICAL DEVICE HAVING AN INTERNAL CIRCULATION UNIT

(71) Applicant: SIEMENS AKTIENGESELLSCHAFT, MUENCHEN (DE)

(72) Inventors: FLORIAN BACHINGER, ST. GEORGEN/GUSEN (AT); KURT KAINEDER, ENGERWITZDORF (AT); GERNOT NEUMUELLER, LICHTENBERG (AT)

(21) Appl. No.: 16/772,942

(22) PCT Filed: Nov. 19, 2018
(86) PCT No.: PCT/EP2018/081670

§ 371 Date: Jun. 15, 2020

(30) Foreign Application Priority Data
Dec. 15, 2017 (DE) 10 2017 222 904.7

(51) Int. Cl. H05K 7/20; F01P 5/10; H01F 27/10; F28F 9/26

(52) U.S. Cl. CPC H05K 7/209; H05K 7/20418; F28F 2250/08; H01F 27/10; F28F 9/262; F01P 5/10

(57) ABSTRACT

An electrical device, such as a transformer, for connection to a high-voltage network, includes a tank which has an internal chamber filled with an insulating fluid and in which a magnetizable core and at least one winding are disposed. A cooling system having at least one radiator which is disposed outside the tank is connected to the tank for circulating the insulating fluid through the radiator. In order to cost-effectively accelerate a cold start, a circulation unit is disposed at least partially in the tank and is configured for circulating the insulating fluid in the tank.

The invention relates to an electrical device for connecting to a high-voltage power grid, having a tank, the interior space of which is filled with an insulating fluid and in which a magnetizable core and at least one winding are arranged, and a cooling system, which comprises at least one radiator, which is arranged outside the tank and is connected to it for circulating the insulating fluid by way of the radiator.

Such a device is known from practice to a person skilled in the art. Thus, for example, transformers have a tank filled with insulating fluid in which a magnetizable core is arranged. The core forms limbs, which are respectively arranged concentrically in relation to a lower-voltage winding and higher-voltage winding enclosing them. The insulating fluid serves for the electrical insulation of the windings, which are at a high voltage potential during the operation of the transformer, with respect to the tank, which is at ground potential. In addition, the insulating fluid provides the necessary cooling of the windings. For this purpose, the insulating fluid heated by the windings is circulated by way of radiators attached to the outside of the tank.

The viscosity of the insulating fluid is temperature-dependent and increases very strongly with falling temperatures. On account of the increased viscosity, at low outside temperatures, below −10° C., the circulation of the insulating fluid by way of the radiator or radiators is impaired. This is problematic in particular when the electrical device has been stationary for a considerable time, since the insulating fluid has then cooled down completely. The high viscosity has to be taken into account when cold starting the electrical device with regard to the reduced cooling power of the cooling system, since the windings can otherwise become overheated.

A transformer is therefore started for example under no load or under reduced load. If the electrical device has active cooling, pumps for circulating the insulating fluid by way of the radiator can only be switched on when the insulating fluid in the tank has exceeded a minimum temperature threshold value. In some cases, however, this temperature threshold value is only reached after several days.

In addition, alternative insulating fluids, such as ester oils and silicone oils, are increasingly being used in electrical devices of the aforementioned type. Although ester oils as insulating fluids have improved environmental compatibility, it is disadvantageous that, at temperatures in the range of below −10° C., they can have such a high viscosity that cold starting of the electrical device has become virtually impossible.

DE 317410 discloses an oil circuit-breaker that has a tank filled with a mineral oil. In the upper region of the tank there extends a flow path, which is heated during the operation of the electrical device. In particular after cold starting, the oil heated by the flow path only circulates in the upper region of the tank. In order also to obtain the oil from the lower region for cooling, an outer bridging pipe fitted with a heating element is provided on the tank. In addition, auxiliary devices with a pump are known, which move the insulating fluid by means of cooling pipes attached to the outside of the tank.

The object of the invention is to provide an electrical device of the type stated at the beginning with which cold starting is speeded up at low cost and can even be carried out at low temperatures.

The invention achieves this object by a circulation unit, which is arranged at least partially in the tank and is designed for circulating the insulating fluid within the tank.

The invention provides an electrical device which, for making cold starting easier, is itself capable of circulating the insulating fluid in the tank, without it being cooled at a cooling device attached to the outside of the tank. Therefore, within the invention there is no notable heat dissipation and no renewed cooling down of the insulating fluid in components arranged outside the tank. The circulation of the insulating fluid within the tank has the effect that, when cold starting the electrical device, the entire insulating fluid arranged in the tank is fed to the heated active part and is heated up by it. It has surprisingly been found that the circulation of the insulating fluid inside the tank alone is sufficient for speeding up cold starting at low cost. The invention therefore provides an effective and at the same time low-cost means with which cold starting is made possible even at very low temperatures of below −10 degrees Celcius.

Advantageously, the pump is arranged outside the tank. In this way, the pump is accessible from the outside, and so maintenance of the pump, and consequently of the circulation unit, is made easier overall.

According to a further variant of the invention, the pump outflow or the pump inflow opens out in the region of an outlet of a connecting line, which connects the tank to the radiator, in the interior space of the tank. According to this further development, the inflow or outflow of the radiator is hydraulically coupled to the inflow or outflow of the pump in the sense that the flow produced by the pump entrains insulating fluid from the radiator, or in other words sucks it out or forces it in, thereby assisting the circulation of the gradually heating insulating fluid by way of the radiator.

Advantageously, the cooling system is a passive cooling system. Within the scope of the invention, the cooling system may however also have a cooling system pump, which is provided for circulating the insulating fluid by way of the radiator. In the case of a passive cooling system, the flow by way of the radiator takes place solely on the basis of a difference in density of the insulating fluid. If hot, and consequently comparatively light, insulating fluid gets into the radiator by way of an upper inflow, it cools down slowly. As it does so, it becomes heavier and sinks down, until it returns by way of a lower radiator outflow into the tank, in order to be heated up again there by the active part.

Advantageously, the cooling system has a number of radiators. A number of radiators allows a greater cooling capacity than just one radiator.

Furthermore, within the scope of the invention, further means may be used in combination to speed up the cold starting of the electrical device according to the invention, or to make it possible at all in the first place. Thus, each radiator advantageously has heat exchange elements arranged parallel to one another and is fitted with an upper radiator inflow and a lower radiator outflow. The radiator inflow and radiator outflow are respectively connected to the tank and to one another by way of heat exchange elements. The heat exchange element that is at the smallest distance from the tank is fitted with a heating element or a heat insulation. The heating element heats the insulating fluid conducted by way of the innermost heat exchange element, and therefore additionally speeds up cold starting. Instead of the active heating of the insulating fluid in the innermost heat exchange element, it may also be provided with a heat insulating unit, which reduces the heat transfer from the insulating fluid in the innermost heat exchange element to the outside atmosphere. The heat insulating unit is for example embodied as a heat insulating layer and encloses the innermost heat exchange element partially or fully circumferentially.

Advantageously, the pump inflow opens out in an upper region of the tank into its interior space. According to this further development of the invention, when cold starting, the pump sucks warmer insulating fluid into the circulation unit, since the heated insulating fluid collects in the upper region of the tank on account of its lower density in comparison with colder insulating fluid. This speeds up cold starting still further.

Further refinements and advantages of the invention are the subject of the following description of exemplary embodiments of the invention with reference to the figures of the drawing, in which the same designations refer to components acting in the same way and in which

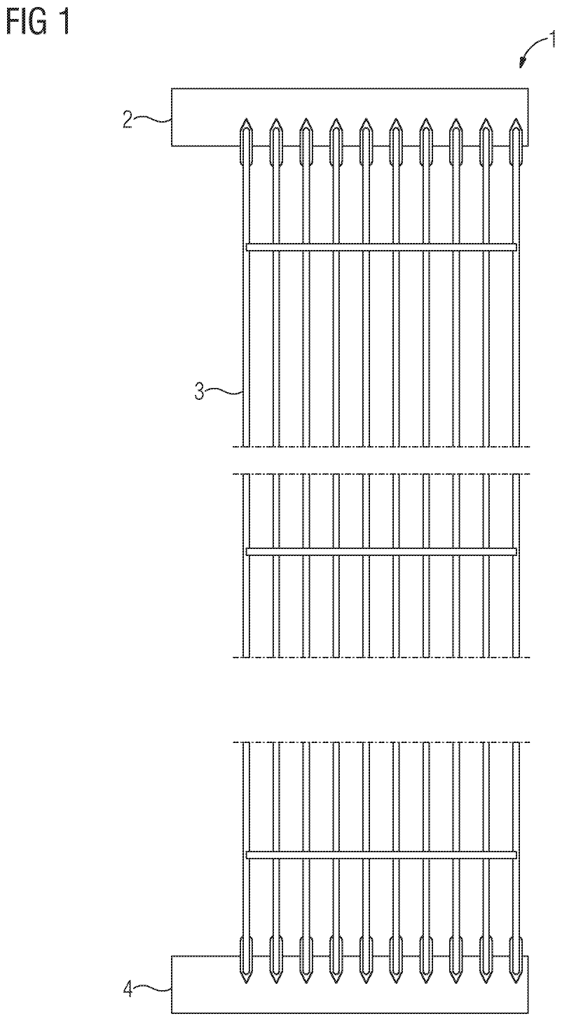

FIG. 1 shows a commercially available radiator in a side view,

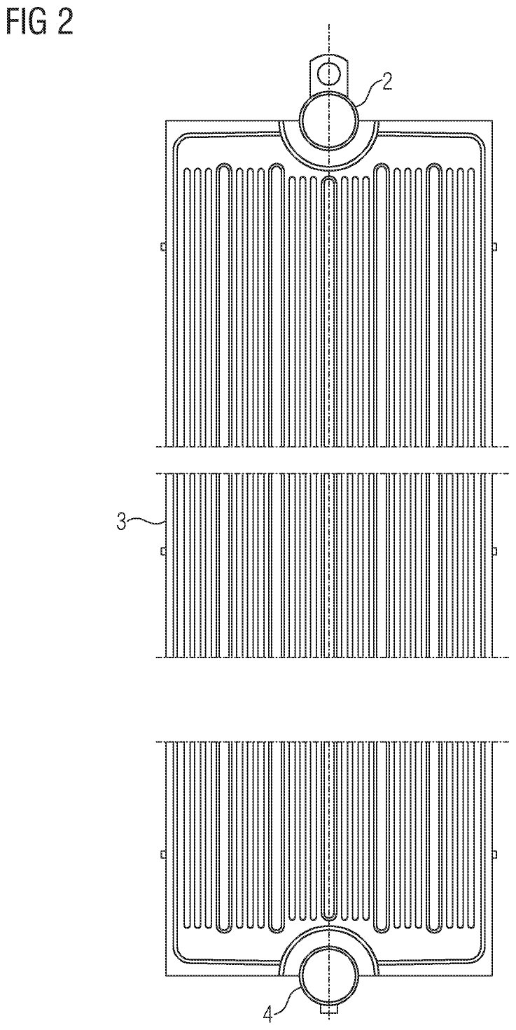

FIG. 2 shows a heat exchange element of the radiator according to FIG. 1 in a plan view,

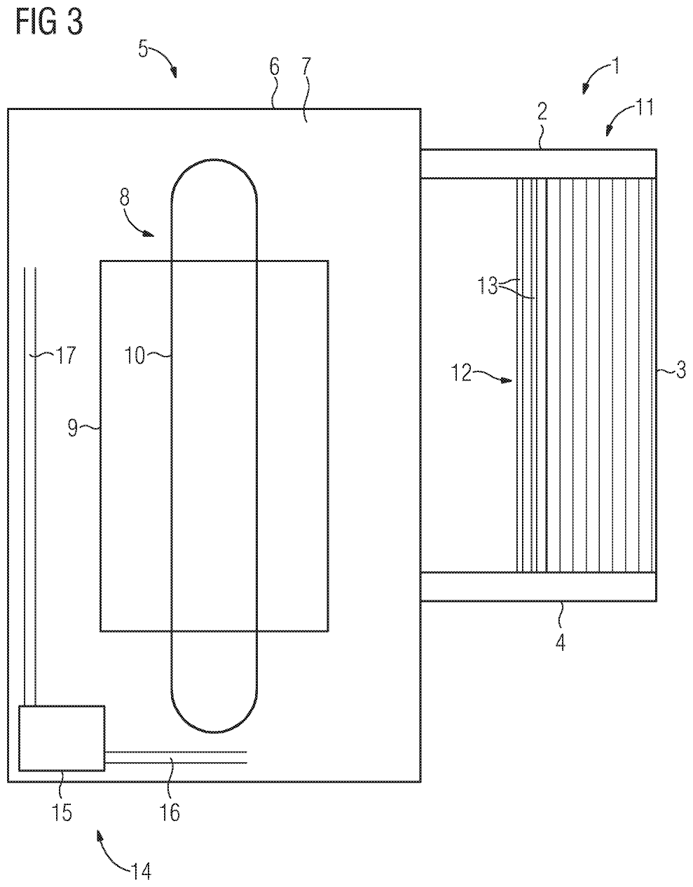

FIG. 3 shows an exemplary embodiment of the electrical device according to the invention in a schematic side view and

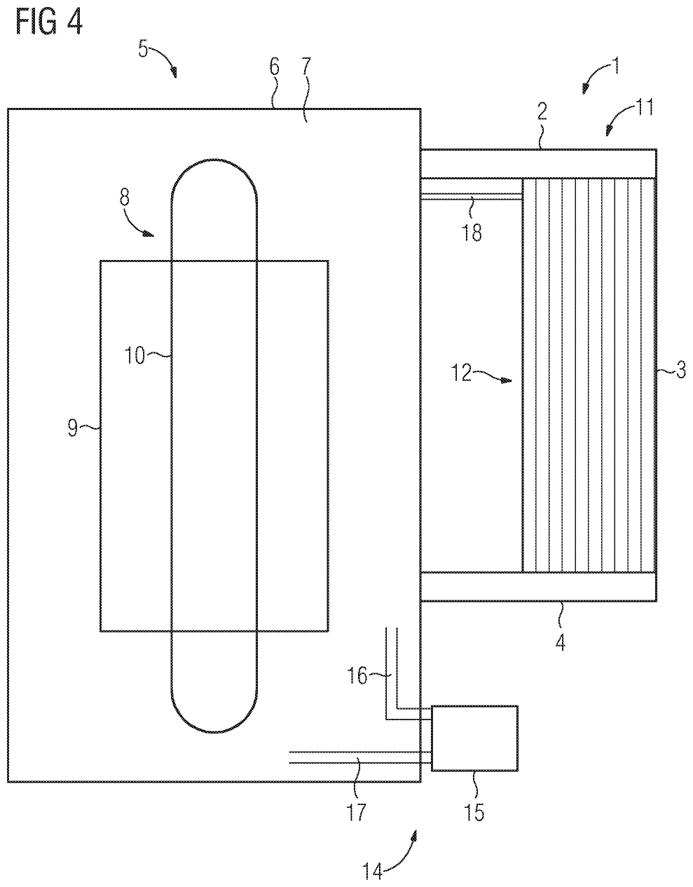

FIG. 4 shows a further exemplary embodiment of the electrical device according to the invention in a schematic side view.

FIG. 1 shows an exemplary embodiment of a commercially available radiator 1 in a schematic side view. It can be seen that the radiator 1 has an upper radiator inflow 2, which is hydraulically connected by way of heat exchange elements or radiator elements 3 to a return 4. The radiator inflow 2 and the radiator return 4 respectively have a left-facing inlet opening and outlet opening, by way of which the radiator 1 after its installation communicates with the interior space of a tank that is not represented in FIG. 1. The insulating fluid of said tank can then be circulated by way of the radiator inflow 2, the heat exchange elements 3 and the radiator return 4 by way of the radiator 1 with its heat exchange elements 3. The heat exchange elements 3 are produced from a heat-conductive material such as a metal and are in thermal contact with the outside atmosphere. If the insulating fluid is conducted via the heat exchange elements, heat is consequently dissipated by the heated insulating fluid to the colder outside atmosphere.

FIG. 2 shows a heat exchange element 3 in an end view. It can be seen that the heat exchange elements 3 are formed as plates. In other words, the radiator 1 shown in FIG. 1 is a so-called plate radiator. The plate-shaped heat exchange elements 3 each bound flow ducts through which the insulating fluid circulated by way of the heat exchange elements 3 is conducted. Finally, the insulating fluid passes into the collecting return line 4 and from there goes back into the interior space of the tank as cooled insulating fluid.

It should however be pointed out in this connection that, within the scope of the invention, the heat exchange elements can in principle be designed in any way desired, and are for example embodied as tube radiators.

FIG. 3 shows an exemplary embodiment of the electrical device 5 according to the invention, which is embodied here as a transformer. The transformer 5 has a tank 6, which is filled with an insulating fluid 7. In addition, arranged in the tank 6 are a magnetizable core 8 and windings 9, of which however only one winding is schematically indicated in FIG. 3. However, here the windings 9 comprise a so-called higher-voltage winding and a so-called lower-voltage winding, which are arranged concentrically in relation to a limb 10 of the core 8. The method of functioning of such a transformer 5 is however known to a person skilled in the art, and so this is not discussed any more specifically at this stage. The necessary connecting lines for connecting the windings to a high-voltage power grid are likewise not shown in the figures for reasons of maintaining an overview.

The transformer 5 is equipped with a cooling system 11, which is attached to the outside of the tank 6 and here comprises just one radiator 1 according to FIG. 1. It can be seen that the radiator inflow 2 and the radiator return 4 open out into the interior space of the tank 6. Since the radiator inflow 2 and the radiator return 4 are connected to one another by way of heat exchange elements 3, circulation of the insulating fluid 7 by way of the radiator 1 is made possible. A heat exchange element 3 that is at the smallest distance from the tank 6, the so-called innermost radiator element 12, is fitted with a heat insulating unit 13. The heat insulating unit 13 consists of a heat insulating layer 13, which encloses the radiator element 12 fully circumferentially. The heat insulating layer 13 is shown in FIG. 3 in a sectional view. A customary adhesive-bonding connection serves for fastening the heat insulating unit on the radiator element 12.

To speed up cold starting, arranged in the interior of the tank 6 is a circulation unit 14, which comprises a pump 15, a pump inflow 16 and also a pump outflow 17. The circulation unit 14 is arranged completely within the tank 6. During operation, the pump 15 takes in insulating fluid 7 by way of the pump inflow 16 and allows it to enter the interior space of the tank 6 again, with a directed flow, at the mouth of the pump outflow 17. In this case, the shape of the pump outflow 17 determines where said point of entry in the tank 6 lies and the direction of the induced flow. In FIG. 3, it is only by way of example that the pump outflow 17 is represented as a vertical pipe, the outlet opening or mouth of which lies in the vicinity of the active part consisting of the core 8 and the windings 9. In this way, the insulating fluid 7 is continuously conducted past the active part 8 and 9 by the internal circulation by means of the circulation unit 14.

After a relatively long stationary state of the transformer 5, the insulating fluid 7 has completely cooled down. In particular at low outside temperatures, for example in the range of −10° C. to −50° C., the insulating fluid 7 has such a high viscosity, is in other words so viscous, that even after a relatively long starting process it is no longer circulated by way of the radiator 1. For this reason, the heat insulating unit 13 is provided, which ensures that insulating fluid that has only been heated up slightly is not cooled down again right away in the innermost heat exchange element 12. Consequently, within the scope of the invention, the higher-voltage winding of the windings 9 can be connected to the high-voltage power grid. By contrast, a resistor expedient for this purpose is applied to the lower voltage winding, and so the transformer 5 is not operated under full load. In this situation, gradual heating of the insulating fluid 7, and consequently of the outer wall of the tank 6, occurs. The insulating fluid 7 is heated more uniformly by the internal circulation by means of the circulation unit 14. The continuous heating of the insulating fluid 7 that is gradually established gradually transfers itself also to the heat exchange elements 3 of the radiator 1, until finally the desired operating state is reached.

FIG. 4 shows a further exemplary embodiment of the transformer 5 according to the invention, which corresponds to the greatest extent to the exemplary embodiment shown in FIG. 3. However, by contrast with the exemplary embodiment shown in FIG. 3, the pump 15 is arranged outside the tank 6, the pump inflow 16 and the pump outflow 17 respectively extending through the wall of the tank 6 into the interior space of the tank 6. Sealing means that are not shown in the figures ensure that the insulating fluid 7 cannot escape from the tank 6. It can be seen that the mouth or opening of the pump inflow 16 lies in the region of the mouth of the radiator outflow 4. The mouth of the radiator outflow 4 may also be referred to more generally as the outlet of a connecting pipe 4 between the tank and the radiator 1. The same applies correspondingly to the inlet of the inflow 2. In the exemplary embodiment shown in FIG. 4, the pump outflow 17 opens out below the windings 9. As a result of the internal circulation, the pump 15 sucks insulating fluid out from the region of the mouth of the radiator outflow 4. This produces a suction effect, which assists the circulation of the insulating fluid by way of the heat exchange elements 3 of the radiator 1.

The innermost heat exchange element 12, which is at the smallest distance from the tank 6, is no longer fitted with a heat insulating unit. Instead, a heat pipe 18 extends as a heating element between the innermost heat exchange element 12 and the wall of the tank 6. When cold starting, first heating of the tank 6 occurs, the heat being transferred by way of the heat pipe 18 to the inner heat exchange element 12, and so cold starting is also speeded up in this way. The operating principle of a heat pipe is known to a person skilled in the art, and so there is no need for it to be explained. Instead of a heat pipe 18, the innermost heat exchange element may also be heated by some other heating element.

In the case of the exemplary embodiments shown in FIGS. 3 and 4, the inlet opening of the pump inflow 16 is arranged in the lower region of the tank 6. Within the scope of the invention, the inlet opening of the pump inflow 16 may however also be arranged in the upper region of the tank. The insulating fluid is warmer in the upper region than in the lower region, and so heat is distributed even more quickly.

Finally, it should be noted that, within the scope of the invention, load control in the case of cold starting can be varied as desired. As a departure from the ways of implementing cold starting mentioned above, the electrical device according to the invention may also be started under full load.

1-8. (canceled)

9. An electrical device for connection to a high-voltage power grid, the electrical device comprising:
a tank having an interior space to be filled with an insulating fluid;
a magnetizable core and at least one winding disposed in said tank;
a cooling system including at least one radiator disposed outside said tank, said at least one radiator connected to said tank for circulating the insulating fluid through said at least one radiator; and
a circulation unit disposed at least partially in said tank, said circulation unit configured for circulating the insulating fluid in said tank.

10. The electrical device according to claim 9, wherein said circulation unit includes a pump fitted with a pump inflow and a pump outflow, said pump inflow and said pump outflow opening out into said interior space of said tank.

11. The electrical device according to claim 10, wherein said pump is disposed outside said tank.

12. The electrical device according to claim 10, which further comprises a connecting pipe connected between said at least one radiator and said tank, said connecting pipe has an outlet, and said pump outflow or said pump inflow opens out in a region of said outlet of said connecting pipe into said interior space.

13. The electrical device according to claim 9, wherein said cooling system is a passive cooling system.

14. The electrical device according to claim 9, wherein said at least one radiator of said cooling system is a plurality of radiators.

15. The electrical device according to claim 14, wherein:
each of said radiators includes mutually parallel heat exchange elements, an upper radiator inflow and a lower radiator outflow;
said upper radiator inflow and said lower radiator outflow are connected to said tank and are connected to one another by said heat exchange elements;
one of said heat exchange elements is disposed at a smaller distance from said tank than others of said heat exchange elements; and
a heating element or a heat insulation is fitted to said heat exchange element disposed at said smaller distance from said tank.

16. The electrical device according to claim 10, wherein said pump inflow opens out into said interior space at an upper region of said tank.
